(19) United States
(12) Patent Application Publication
(10) Pub. No.: US 2007/0155152 A1
(43) Pub. Date: Jul. 5, 2007

(54) METHOD OF MANUFACTURING A COPPER INDUCTOR

(76) Inventor: Myung II Kang, Gyeonggi-do (KR)

Correspondence Address: SHERR & NOURSE, PLLC, 620 HERNDON PARKWAY, SUITE 200, HERNDON, VA, 20170, US

(21) Appl. No.: 11/617,197

(22) Filed: Dec. 28, 2006

(30) Foreign Application Priority Data
Dec. 29, 2005 (KR) 10-2005-0133461

(51) Int. Cl. H01L 21/44

(52) U.S. Cl. 438/597

(57) ABSTRACT

An inductor can be integrated with other components in a device formed on one semiconductor chip. The integrated circuit inductor has reduced electric resistance in the conductor and minimized influence on other circuit elements. A method of manufacturing the inductor which minimizes the area occupied by the inductor in a semiconductor chip allows the chip to be located in a small, narrow region along the edge of a chip, with coils which are vertically aligned with respect to the semiconductor substrate.

The present application claims priority under 35 U.S.C. 119 and 35 U.S.C. 365 to Korean Patent Application No. 10-2005-0134461 (filed on Dec. 29, 2005), which is hereby incorporated by reference in its entirety.

### BACKGROUND

An inductor is a circuit component which may be used to transmit and receive radio frequency (RF) signals, which has become more commercially important due to the increase in the wireless communication market.

An inductor generally has a spiral shape. One disadvantage of a spiral shaped inductor is that the self-resonanant frequency of the inductor is reduced due to parasitic capacitance between metal interconnections.

The self-resonant frequency in an inductor is the frequency at which the effective impedance of the inductance equals the effective impedance of the parasitic capacitance.

Inductors are mainly used at frequency lower than the self-resonant frequency. In a spiral shaped inductor, since the size of the structure increases the parasitic capacitance, the self-resonant frequency is reduced, and the usable frequency band is reduced.

In a semiconductor integrated circuit device, the inductor is formed over an external additional substrate area and then is connected to the internal circuit of a device.

This is because the spiral inductor locally affects other elements on a semiconductor substrate because of the vertical magnetic field generated into the semiconductor substrate.

That is, the inductor induces current around semiconductor elements and the induced current forms an electric field which tends to oppose the action of the inductor, so that the performance of the inductor is further compromised.

For this reason, it is difficult to integrate an inductor into a single chip device. Also, when the inductor is formed on a single chip, since the inductor is formed of aluminum, the conductance of a conductor that constitutes the inductor degrades.

### SUMMARY

Embodiments relate to a method of manufacturing an inductor that can be integrated with other components in a device formed on one semiconductor chip.

Embodiments relate to a method of manufacturing an integrated circuit inductor with reduced electric resistance in the inductor and with minimized influence on other circuit elements.

Embodiments relate to a method of manufacturing an inductor which minimizes the area occupied by the inductor in a semiconductor chip.

In order to achieve the above objects, a method of manufacturing a copper inductor includes laminating a first barrier insulating layer and first interlayer dielectric layer over a semiconductor substrate to form a first laminated layer. The barrier insulating layer may include SiN or SiC. A first trench is formed in the first laminated layer. A first barrier metal layer is applied over the internal wall of the first trench. A first copper metal layer is formed over the first barrier metal layer to completely fill the first trench, thereby forming a first metal interconnection layer.

A second laminated layer is formed similarly to the first laminated layer. A second trench having a double damascene structure is formed in the second laminated layer. The second metal interconnection is completed similarly to the first.

A third metal interconnection layer is formed over the second metal interconnection layer using the same techniques used for forming the second metal interconnection layer.

The first metal layer and the second metal layer are electrically connected to each other by a via connection included in the double damascene trench structure of the second metal layer, and the second metal layer and the third metal layer are electrically connected to each other by a via connection included in the double damascene trench structure of the third metal layer.

The interlayer dielectric layer is formed of a first capping layer, a fluorinated silicate glass (FSG) layer, and a second capping layer.

The first to third metal interconnection layers form rectangular spirals, which are aligned vertically with respect to the semiconductor substrate. The end of the first metal interconnection layer and the end of the third metal interconnection layer are terminals of an inductor.

### BRIEF DESCRIPTION OF DRAWINGS

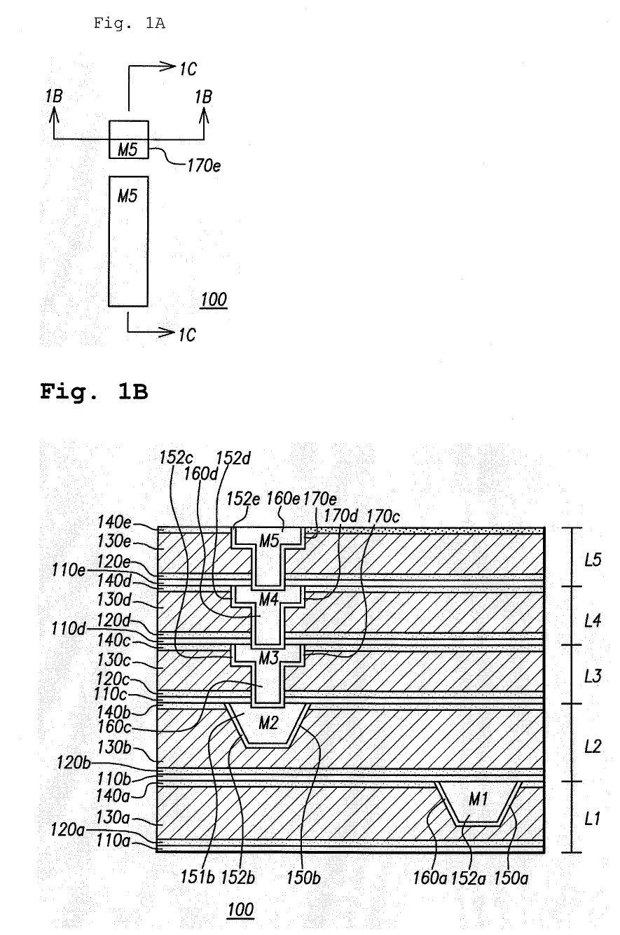

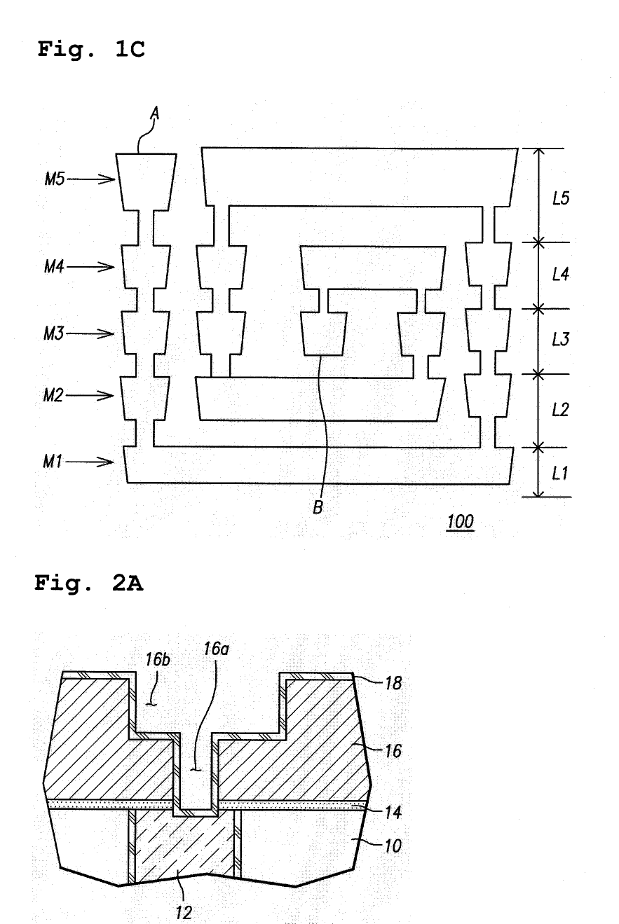

Example FIG. 1A is a plan view of a copper inductor according to embodiments.

Example FIG. 1B is a sectional view taken along the line 1B-1B of FIG. 1A.

Example FIG. 1C is a sectional view taken along the line 1C-1C of FIG. 1A; and

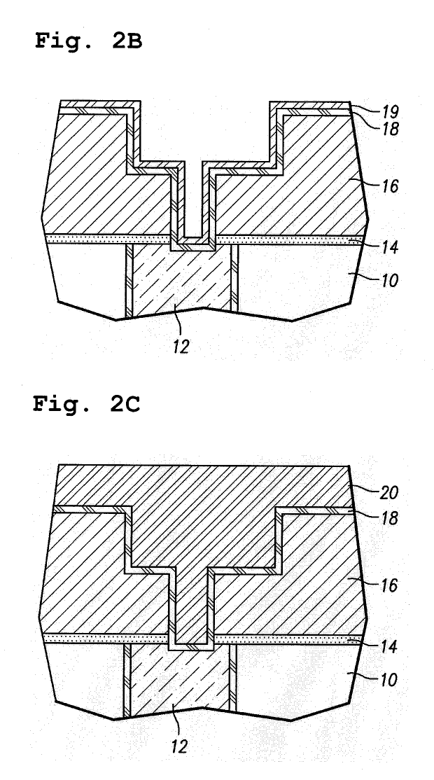

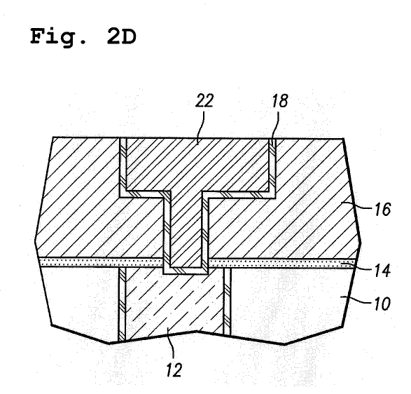

Example FIGS. 2A to 2D are sectional views for describing a damascene process used for manufacturing a copper inductor according to embodiments.

### DETAILED DESCRIPTION

Referring to FIGS. 1A to 1C, a copper inductor 100 according to embodiments is composed of five layers L1, L2, L3, L4, and L5 vertically stacked over a semiconductor (not shown). The layers include copper metal layers M1, M2, M3, M4, and M5, respectively.

The copper inductor in FIG. 1 is described as having the five layers. However, the number of layers is not limited to five but varies in accordance with the capacity of the inductor to be integrated. The copper metal layers constitute the conductor of the inductor.

As illustrated in FIG. 1C, in the copper inductor 100 according to embodiments, copper metal layers are connected to each other in a rectangular spiral. The plane of the functional coils in the spiral is vertical with respect to the semiconductor substrate.

In FIG. 1C, A and B denote both terminals of the inductor 100. As described above, since the copper inductor 100 according to embodiments has rectangular spirals aligned to be vertical with respect to the semiconductor substrate, the copper inductor 100 does not occupy a large amount of the horizontal space of a semiconductor chip. The copper inductor according to embodiments can be formed in a small space. For example, the inductor can be formed at a narrow and long edge region on the chip where circuit elements such as transistors are not formed.

The manufacturing processes of the copper inductor 100 according to embodiments are as follows.

As shown in FIG. 1B, a barrier insulating layer 110a, a first capping layer 120a, a fluorinated silicate glass (FSG) layer 130a, and a second capping layer 140a are sequentially laminated over a semiconductor substrate and a trench 150a is formed in the laminated layers.

A barrier metal layer 152a is applied over the internal wall of the trench 150a and a copper metal layer 160a is formed over the barrier metal layer 152a to completely fill the trench 150a. The copper metal layer 160a corresponds to the first metal interconnection M1 of the inductor 100.

Thus, the first layer L1 is formed. Although not shown in FIG. 1A, circuit elements such as a metal oxide semiconductor (MOS) transistor are formed under the barrier insulating layer 110a and the circuit elements are covered with an insulating layer.

Then, the second layer L2 is formed over the first layer L1 using the same processes as the processes forming the first layer L1.

A barrier insulating layer 110b, a first capping layer 120b, an FSG layer 130b, and a second capping layer 140b are sequentially laminated over the first layer L1.

Then, after forming a trench 150b on the laminated layers, a barrier metal layer 152b is applied over the internal wall of the trench 150b. A metal layer 160b is formed to completely fill the trench 150b. The second layer L2 constitutes the second metal interconnection M2 of the inductor.

Then, the third layer L3, the fourth layer L4, and the fifth layer L5 are laminated using the above methods. The first to fifth metal interconnections M1 to M5 are connected through a double damascene structure.

In the sectional view of FIG. 1A, since the connection between the first metal interconnection and the second metal interconnection is not illustrated, the double damascene is not expressed with respect to the first and second metal interconnections M1 and M2.

According to embodiments, the metal interconnections are electrically connected to each other by the via portion of the metal interconnections M1 to M5.

The formation of the metal interconnection using the double damascene process will be described with reference to FIGS. 2A to 2D.

Referring to FIG. 2A, a barrier insulating layer 14 is formed over a first interlayer dielectric layer 10 where a lower metal interconnection 12 is formed.

Here, the lower metal interconnection 12 may be one of the first to fourth metal interconnections and the first interlayer insulating layer 10 may refer to the first capping layer 120, the FSG layer 130, and the second capping layer 140 in FIG. 1B.

The FSG layer 130 has a low dielectric constant but emits a fluorine gas which can corrode an oxide layer. Therefore, the capping layers 120 and 140 are applied under and over the FSG layer 130 to prevent the oxide layer from being corroded by the FSG layer 130.

The capping layers 120 and 140 are, for example, SiH4. The first interlayer dielectric layer 10 is made as thick as necessary to make the metal interconnection layers long enough to form inductor 100. The barrier insulating layer 14, which may be formed of SiN or SiC, functions as an etch stop layer in the process of forming a damascene pattern.

After forming the barrier insulating layer 14, a second interlayer dielectric layer 16 is formed over the barrier insulating layer 14. The second interlayer dielectric layer 16 is formed using the same material and processes as the first interlayer dielectric layer 10.

After forming the second interlayer dielectric layer 16, a damascene pattern composed of a via 16a and a trench 16b is formed in the second interlayer dielectric layer 16 using the barrier insulating layer 14 as the etch stop layer.

Then, after removing a part of the barrier insulating layer 14 exposed by a via 16b, a barrier metal layer 18 is formed over the entire surface of the second interlayer dielectric layer 16.

The barrier metal layer 18 is uniformly applied over the internal walls of the via 16a and the trench 16b. The barrier metal layer 18 can be formed of a Ta based compound (such as TaN, or TaSiN) or other compound (such as Ti/TiN, and WNx) that is well adhered to copper and that can effectively prevent the copper from diffusing into surrounding regions.

Then, as illustrated in FIG. 2B, a copper seed layer 19 is applied over the barrier metal layer 18.

Then, as illustrated in FIG. 2C, a copper layer 20 that sufficiently fills the via 16a and the trench 16b is formed over the copper seed layer 19 by an electrochemical plating (ECP) method.

Referring to FIG. 2D, the copper layer 20 is polished by a chemical mechanical polishing (CMP) method until the second interlayer dielectric layer 16 is exposed. This completes a copper metal interconnection 22.

According to embodiments, since the inductor is formed of copper, which has a low resistivity, it is possible to prevent the performance of the inductor from degrading because of a change in temperature. An additional large area is not required to accomodate the inductor in the chip. The inductor can be manufactured using a narrow area along an edge.

Also, according to embodiments, since the integrated circuit element and the inductor are formed together on one chip, rather than forming the inductor on a separate substrate, it is possible to create a single integrated chip which includes the inductor with other devices, such as transistors.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising forming a plurality of elements of an inductor by a damascene process.

2. The method of claim 1, wherein the inductor is a copper inductor.

3. The method of claim 1, comprising laminating a first barrier insulating layer and first interlayer dielectric layer over a semiconductor substrate to form a first laminated layer, wherein the first barrier insulating layer and first interlayer dielectric layer are comprised in an element of the inductor.

4. The method of claim 3, comprising:
forming a first trench in the first laminated layer;
applying a first barrier metal layer over the internal wall of the first trench; and
forming a first copper metal layer over the first barrier metal layer to completely fill the first trench to form a first metal interconnection layer.

5. The method of claim 4, comprising:
laminating a second barrier insulating layer and a second interlayer dielectric layer over the first metal interconnection layer to form a second laminated layer;
forming a second trench having a double damascene structure in the second laminated layer; and
applying a second barrier metal layer over the internal wall of the second trench and forming a second copper metal layer over the second barrier metal layer to completely fill the second trench to form a second metal interconnection layer over the first metal interconnection layer.

6. The method of claim 5, comprising:
laminating a third barrier insulating layer and a third interlayer dielectric layer over the second metal interconnection layer to form a third laminated layer;
forming a third trench having a double damascene structure in the third laminated layer; and
applying a third barrier metal layer over the internal wall of the third trench and forming a third copper metal layer over the third barrier metal layer to completely fill the third trench to form a third metal interconnection layer over the second metal interconnection layer.

7. The method of claim 6, wherein the first metal layer and the second metal layer are electrically connected to each other by a via connection included in the double damascene trench structure of the second metal layer.

8. The method of claim 7, wherein the second metal layer and the third metal layer are electrically connected to each other by a via connection included in the double damascene trench structure of the third metal layer.

9. The method of claim 8, wherein the interlayer dielectric layer is formed of a first capping layer, a fluorinated silicate glass (FSG) layer, and a second capping layer.

10. The method of claim 9, wherein:
the first to third metal interconnection layers form rectangular spirals, which are aligned vertically with respect to the semiconductor substrate, and
the end of the first metal interconnection layer and the end of the third metal interconnection layer are terminals of an inductor.

11. The method of claim 9, wherein the barrier insulating layer comprises at least one of SiN and SiC.

12. An apparatus comprising a plurality of elements of an inductor having a damascene structure.

13. The apparatus of claim 12, wherein the inductor is a copper inductor.
